(19) United States
(12) Patent Application Publication
(10) Pub. No.: US 2026/0173276 A1
(43) Pub. Date: Jun. 18, 2026

(54) SEPARATING MACHINE FOR SEPARATING INDIVIDUAL PRINTED CIRCUIT BOARDS FROM A PRINTED CIRCUIT BOARD PANEL, AND METHOD

(71) Applicant: SCHUNK Electronic Solutions GmbH, St. Georgen (DE)

(72) Inventor: Dominik Bösinger, St. Georgen (DE)

(21) Appl. No.: 18/876,418

(22) PCT Filed: Jun. 21, 2023
(86) PCT No.: PCT/EP2023/066833

§ 371 Date: Dec. 18, 2024

(30) Foreign Application Priority Data
Jun. 21, 2022 (DE) 20 2022 103 455.9

(51) Int. Cl. H05K 3/00; H05K 13/08

(52) U.S. Cl. CPC H05K 3/0052; H05K 3/0008; H05K 13/081; H05K 13/083; H05K 2203/0228

(57) ABSTRACT

A separating machine for separating individual printed circuit boards from a printed circuit board panel has a separating head and a separating tool movable on a machine frame. The separating head is movable by axis drives and has base plates movable by linear direct drives on the machine frame between loading and separating positions. A printed circuit board panel is arrangeable on each of the base plates. Linear direct drives comprise a motor part and a magnetic rail that interacts with the motor part. A control unit actuates the axis drives, the separating head, and the linear direct drives. The separating tool separates individual printed circuit boards from a printed circuit board panel during the separation processing. The linear direct drives can be controlled independently of one another.

### DESCRIPTION

The invention relates to a separating machine for separating individual printed circuit boards from a printed circuit board panel, which are also referred to as circuit board panels or PCB panels. The invention also relates to a method for operating a separating machine of this kind.

In the production of electronics, which is industrial and highly automated, the use of highly efficient and precise manufacturing technology is a basic requirement. In electronics manufacturing, it is necessary to produce very large quantities reliably and to a high standard of quality in order to be able to offer the products at market prices. Therefore, the efficiency of the machines used must be constantly increased. An important method step in the manufacture of electronic assemblies is the separation of printed circuit board panels into individual assemblies, i.e., into individual printed circuit boards, after they have been populated with components and then soldered. Given the complexity of today's assemblies and circuit structures, soiling and contamination, inter alia, of assemblies and printed circuit boards due to the resulting particles and dust are extremely problematic. This not only reduces production yields in electronics manufacturing, but undetected errors in assemblies can have far-reaching consequences for product safety. It is therefore particularly important to capture and separate particles and dust as completely as possible when processing printed circuit board panels and printed circuit boards.

The cycle times of the machines used consist of the assembly time, the processing time and any transition times between the processing steps. These times cannot be adjusted arbitrarily because if, for example, the work is carried out too quickly, the components may be damaged or not soldered properly. This leads to defective batches or subsequent failures in the final products.

A machine for the automated cutting or separating of circuit boards is known from CN112497288B.

The object of the present invention is to increase the process reliability and efficiency when separating individual printed circuit boards from a printed circuit board panel.

The object is achieved, in particular, by a separating machine for separating individual printed circuit boards from a printed circuit board panel according to claim 1.

In particular, the separating machine comprises a separating head that has a separating tool and that can be moved on a machine frame, the separating head being movable by means of axis drives along a vertical z-axis and a y-axis extending perpendicular thereto.

In addition, the separating machine comprises at least two base plates which can be moved on the machine frame parallel to one another along an x-axis extending perpendicular to the z-axis and perpendicular to the y-axis between a loading position and a separating position by means of linear direct drives. At least one printed circuit board panel can be arranged on each of the base plates. The at least one printed circuit board panel can be arranged directly on the base plate; however, it is also conceivable for the at least one printed circuit board panel to be arranged indirectly on the relevant base plate via a holding device.

The linear direct drives each comprise a motor part and a magnetic rail that interacts with the motor part.

The separating machine further comprises a control unit for controlling the axis drives, the separating head and the linear direct drives, the control unit being configured such that the separating tool separates individual printed circuit boards from a printed circuit board panel during the separation processing. The linear direct drives can be controlled independently of one another, such that one base plate is in the loading position and the other base plate is in the separating position for the separation processing.

A separating machine of this kind has the advantage that the printed circuit board panel can be changed particularly fast, thus achieving low idle times in the production process. By providing at least two base plates, one printed circuit board panel can always be processed in the separating position while the other base plate can be loaded or unloaded in the loading position. This type of separating machine can advantageously increase the efficiency of electronics manufacture.

It is conceivable to design the separating tool as a milling cutter and/or saw and/or laser and/or knife, it being possible to change the tool depending on the printed circuit board panel to be separated. Process reliability can be increased by using a separating tool that is adapted to the separation task. Furthermore, a tool changer can be provided in the separating machine for changing the separating tool.

It is advantageous if the relevant motor part of the linear direct drives is arranged in a fixed position on the machine frame and the relevant magnetic rail is arranged on the relevant base plate. Linear direct drives transmit the drive force magnetically without mechanically interacting transmission media and are therefore maintenance-free and do not cause abrasion, which can lead to dirt in the separating machine. Cables connected to moving components should be bundled and routed in a machine and should not be routed loosely to the relevant moving components. The cables could become trapped by moving parts or the insulation could be worn through, leading to failures. Conventional designs in which the motor part is moved and the magnetic rail is rigidly connected to the machine frame therefore require a cable carrier to route and protect the cables. The unusual arrangement of the motor part and the magnetic rail on the relevant base plate and on the machine frame has the advantage that the cable carrier for cable routing can be dispensed with. This reduces the risk of the separating machine failing due to worn or broken drive cables and also reduces the maintenance workload required for the separating machine. Furthermore, the mass of the moving base plates is reduced not only by eliminating moving cables, but also by arranging the lighter magnetic rail on the base plate instead of on the heavier motor part.

It is conceivable for the relevant motor part to be designed to be guide-free, guide rails being provided at a distance from the relevant motor part to guide the base plates on the machine frame. By separating the drive and guide, the machine can be designed to be particularly easy to maintain. The arrangement of the guide rails, for example at the edge of the base plates, ensures particularly good and stable mounting of the base plates, which improves process reliability.

It is further advantageous if three guide rails having guide carriages and extending parallel to one another are provided for guiding two base plates, a first guide carriage for the first base plate and a second guide carriage for the second base plate being provided on a first, central guide rail. The first, central guide rail therefore has a dual function: firstly, it guides the first base plate and, secondly, it also guides the second base plate.

It is further conceivable for the second and third guide rails to each have at least one and preferably two guide carriages. The guide carriage(s) of the second guide rail is/are provided for guiding the first base plate and the guide carriage(s) of the third guide rail is/are provided for guiding the second base plate. This arrangement saves one guide rail compared to conventional solutions, in which two guide rails are provided for each base plate, i.e., a total of four guide rails.

It is also advantageous if carrier parts are provided between the relevant base plate and the relevant guide carriage. In particular, it is advantageous if, when two guide carriages are provided on a guide rail for a base plate, a common carrier part is provided between the two guide carriages and the one base plate, which is particularly the case with the second and third guide rails. The carrier parts connect the guide carriages to one another and to the base plates. The guide carriages can be used to provide the distance between the base plate and the machine frame, which is required for the linear direct drive or other components below the base plate. Furthermore, the carrier parts ensure improved rigidity of the arrangement, which in turn ensures improved and less wear-prone guidance of the base plates.

It may be advantageous if a carrier part which is L-shaped in plan view is provided in each case on the first, central guide rail between the first guide carriage and the first base plate and/or between the second guide carriage and the second base plate. This L-shaped carrier part allows the base plate to be arranged on the relevant guide carriage of the first central guide rail, such that the base plates can be moved independently of one another. The L-shaped carrier parts have an elongate portion which extends over the entire length of the base plate and a short rectangular portion which extends parallel to the elongate portion and that is arranged at one end of the elongate portion. The two short rectangular portions are arranged each on the relevant opposing sides of the elongate portion. On this short rectangular portion, the guide carriage of the relevant base plate is arranged on the first, central guide rail.

It is conceivable for a base plate to be supported and/or guided in the region of the first, central guide rail by the carrier part of the other base plate. The lower side of the base plate is located in the lateral edge region on the upper side of the L-shaped carrier part of the other base plate. This provides advantageous support for the base plate when processing the printed circuit board panel arranged thereon, in particular when the separating tool exerts a vertical force on the printed circuit board panel and thus on the base plate.

It is also advantageous to provide a position measuring system for detecting the position of the relevant base plates. Advantageously, the position measuring system in each case has a sensor arranged in a fixed position on the machine frame and a signal generator on the relevant base plate which interacts with the sensor. The position measuring system may be designed as a non-contact incremental measuring system or as an absolute measuring system, having a reading head as the sensor and a magnetic tape as the signal generator for the reading head. Detecting the position of the base plates can advantageously be utilized by a control unit of the machine to ensure the process reliability.

It is conceivable to provide at least two loading compartments on the separating machine, in each of which a base plate in the loading position thereof can be loaded with a printed circuit board panel independently of the other loading compartment. It is advantageous if each loading compartment has an individual lockable sliding cover, the control unit and the loading system being configured such that the sliding cover of the relevant loading compartment is locked when the relevant base plate is in the separating position thereof. This can prevent problems when loading the separating machine and also reduce the risk of injury to the operator from moving machine parts or from the separating tool when loading the machine.

It can also be provided for the control unit to be configured such that, during the separation processing, a relative movement between the base plate and the separating head in the direction of the x-axis takes place by actuating the relevant linear direct drive. By using the linear direct drives as the x-axis, an additional axis drive is not needed. Any transfer apparatuses from the loading compartment to the separation processing is also not required. This simplifies the entire mechanics of the separating machine and reduces the probability of failure of the separating machine.

It is also advantageous to arrange the separating head on a gantry in a rigid and immovable manner in the x-axis direction. The gantry is designed such that the base plates underneath can move in the x-direction.

It is also conceivable to design the axis drives of the separating head as linear direct drives, each consisting of a carriage and a guide and in which the drive force is transmitted directly without mechanical transmission elements. As a result, the drive of the separating head is wear-free and thus increases the efficiency and process reliability of the separating machine.

It is also advantageous if the linear direct drives and axis drives each have a drive controller, the control unit then being designed to communicate with the relevant drive controller.

It is also conceivable for the control unit to comprise a process control module for communication with a process control system and/or a machine control module for communication with the drive controllers.

It can be provided for the control unit to be configured to access a database via the process control system.

It is further advantageous if a camera system having at least one camera and a data interface is provided and is configured to record the circuit board panels. The camera system can be used to detect the position of the printed circuit board panel arranged on the base plate and feed said position to the control unit. Furthermore, quality features can be identified on the printed circuit board panel and used for quality assurance measures.

Advantageously, the control unit may comprise a user interface module for communicating with a user interface.

The process data of the separating machine can be displayed on the user interface and/or control commands can be entered via the user interface and transmitted to the control unit.

It can be provided for the control unit to comprise an image processing module and a camera module for communication with the camera system. If a camera system is provided in the separating machine, the camera image material can be processed by means of the image processing module.

It can be provided for an extraction apparatus to be provided in the separating machine for extracting particles when individual printed circuit boards are being separated from a printed circuit board panel. The extraction apparatus provides an extraction opening which extends around a central axis and at least one compressed air nozzle provided for generating a compressed air flow directed in a main air flow direction. The compressed air nozzle is arranged, in particular, within the extraction opening in such a way that the main air flow direction is directed towards the workpiece to be separated. Furthermore, a compressed air line can be provided to supply the compressed air nozzle with compressed air.

A valve unit may be provided within the compressed air line, which is designed to generate a compressed air flow pulsating at a pulse frequency such that particles adhering to the printed circuit board panel and/or the printed circuit board are detached and/or such that the printed circuit board panel and/or the printed circuit board are caused to vibrate due to the impinging pulsating compressed air flow. This can increase the process reliability further.

It can furthermore be provided for the valve unit to be designed as an electrically actuated switching valve and for a control unit to be provided for actuating the switching valve to generate the pulse frequency. This has the advantage that it allows for simple control of the switching valve and integration into a commercially available controller system or machine controller.

It has also proven advantageous if the switching valve is actuated by the control unit such that the pulse frequency is in the range of from 1 to 60 Hz, in particular from 20 to 40 Hz, and more particularly 30 Hz. Advantageously, the pulse frequency of the compressed air flow is transferred to the workpiece and the workpiece then vibrates to remove adhering particles.

It is further conceivable that the control unit is configured to control the switching valve in an open-loop manner depending on workpiece parameters of the printed circuit board panel and/or to control the switching valve in a closed-loop manner depending on a measured vibration frequency. This is advantageous because it ensures even greater process reliability by maintaining tolerances in the vibration frequency.

An ionizer may also be provided for ionizing the compressed air forming the compressed air flow. This allows the ionized compressed air to be generated near the separating machine in order to ensure the best possible ionization of the air molecules used to form the compressed air. It is therefore advantageous if the at least one compressed air nozzle is made of a non-conductive material, in particular a non-conductive plastics material. The non-conductive plastics material advantageously maintains the ionized state of the air molecules and the ionization of the air molecules is not compensated until the compressed air of the compressed air flow strikes the printed circuit board panel and/or the printed circuit board or rather the particles to be removed.

It can furthermore be provided for a nozzle ring to be provided forming the extraction opening, on which nozzle ring the at least one compressed air nozzle and preferably three compressed air nozzles are arranged at an angular distance of 120° from one another. With three compressed air nozzles, an advantageous mass of compressed air can be directed by means of the compressed air flow onto the printed circuit board panel and/or the printed circuit board. By the arrangement of the compressed air nozzles on a component, the mountability on a separating machine is designed in an advantageous manner.

It is advantageous if the main air flow direction of the at least one compressed air nozzle is such that, during operation, the compressed air flow generates a vortex around the central axis.

It can furthermore be provided for the nozzle ring to also have a round outer contour with a flat spot, one or more compressed air connections being provided at the flat spot.

It is also advantageous if the nozzle ring has, on an upper side facing the extraction opening, a circumferential shoulder surrounding the extraction opening and having a shoulder edge and if the at least one compressed air nozzle is provided on the shoulder edge. This has the advantage that the arrangement of the compressed air nozzle on the shoulder edge causes little disturbance to the compressed air flow exiting the compressed air nozzle and that this flow can develop in the best possible way.

The nozzle ring may have an upper side facing the extraction opening and a lower side facing away from the extraction opening, the upper side and lower side being parallel to one another.

It is further conceivable that the nozzle ring has a sensor holder for a tool sensor, a sensor nozzle directed towards the sensor holder being provided. The sensor is configured, in particular, to detect wear or breakage of the separating tool. Due to deposits of particles, the functioning of the sensor may be impaired, since it may be an optical sensor, in particular. The sensor nozzle is advantageously designed to blow off the deposited particles on the sensor by means of compressed air.

It may be advantageous if an extraction system having a vacuum source, having vacuum lines for connecting an extraction apparatus to the vacuum source, and having shifting apparatuses for shifting the vacuum lines to a movable position of the extraction apparatus is provided on the separating machine. Advantageously, the extraction apparatus and the other components are adapted to one another in such a way that the extraction works in an optimal manner and all components work together. This results in an increase in process reliability and efficiency.

The object is also achieved by a method according to claim 28.

Further details and advantageous designs of the invention can be found in the following description, on the basis of which embodiments of the invention are described and explained in more detail.

In the drawings:

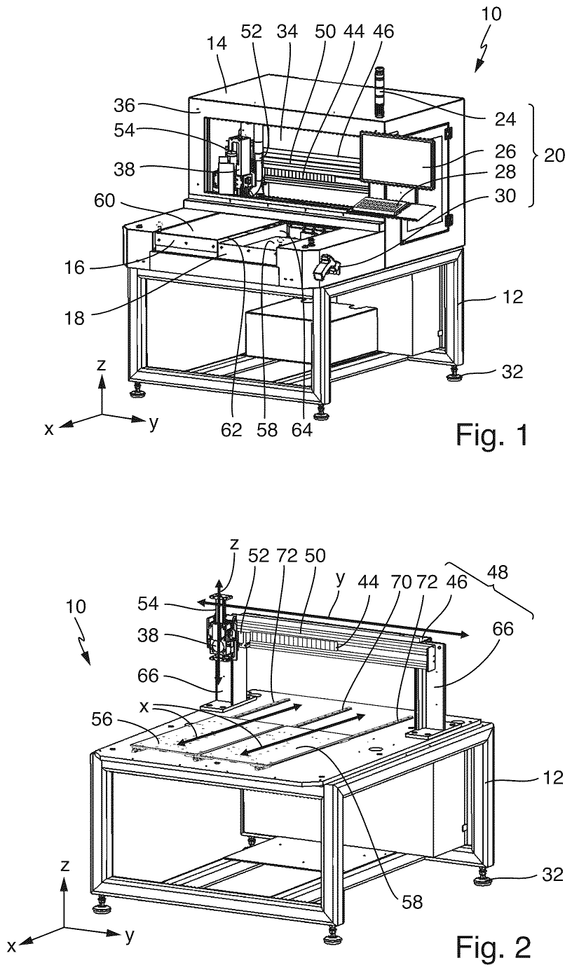

FIG. 1: shows a separating machine for separating individual printed circuit boards from a printed circuit board panel having a display and two loading compartments;

FIG. 2: shows the separating machine according to FIG. 1 without the housing with a view into the interior of the separating machine with a left and right base plate and a movable separating head;

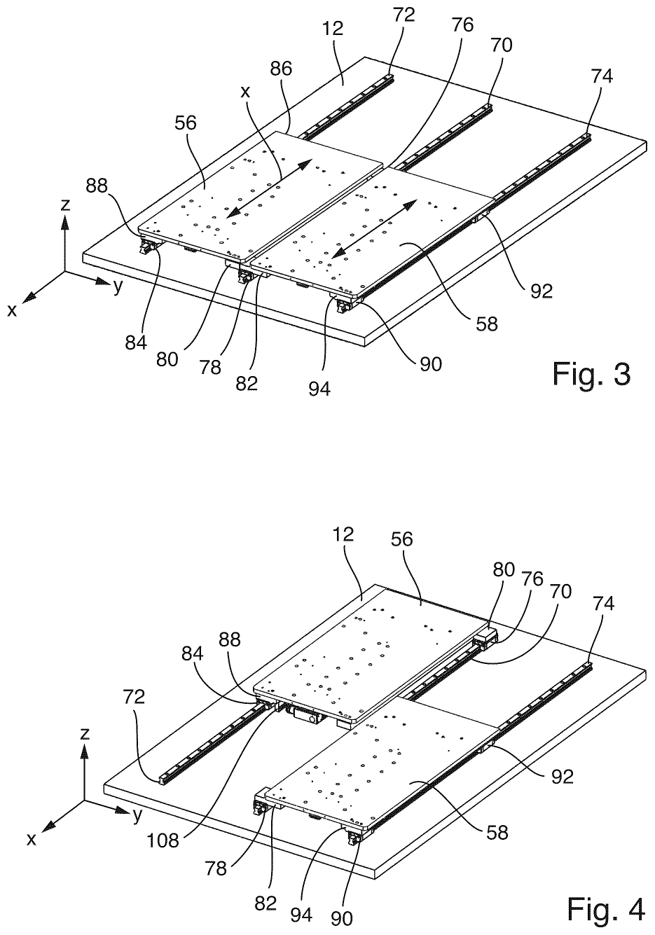

FIG. 3: is a detail view from FIG. 2 of the base plates in a front position with one drive and three guides each;

FIG. 4: shows the view according to FIG. 3 with the left base plate in a front position and the right base plate in a rear position;

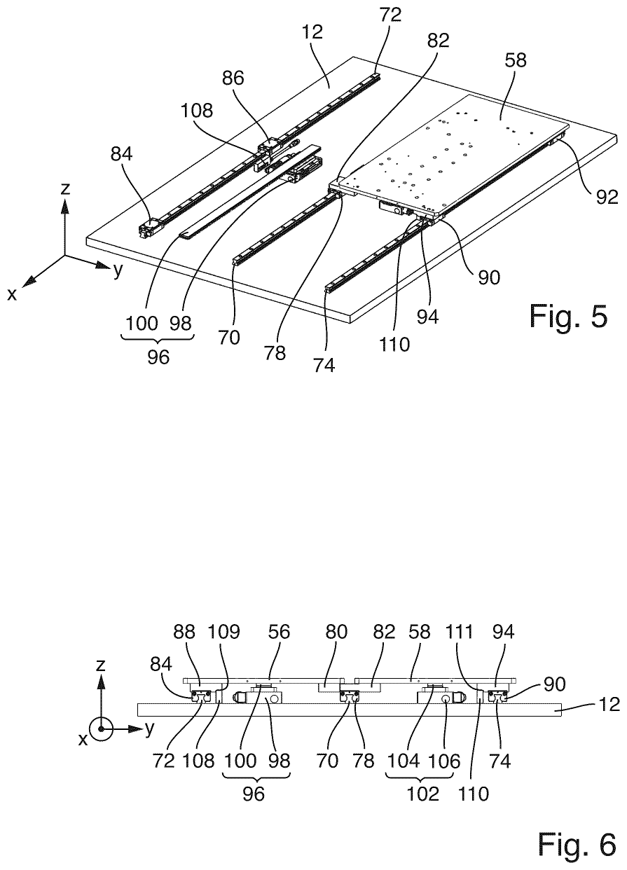

FIG. 5: is a view according to FIG. 4 of the drive and the guide of the left base plate;

FIG. 6: shows the base plates with guides and drives according to FIG. 3 to 5 in a front view;

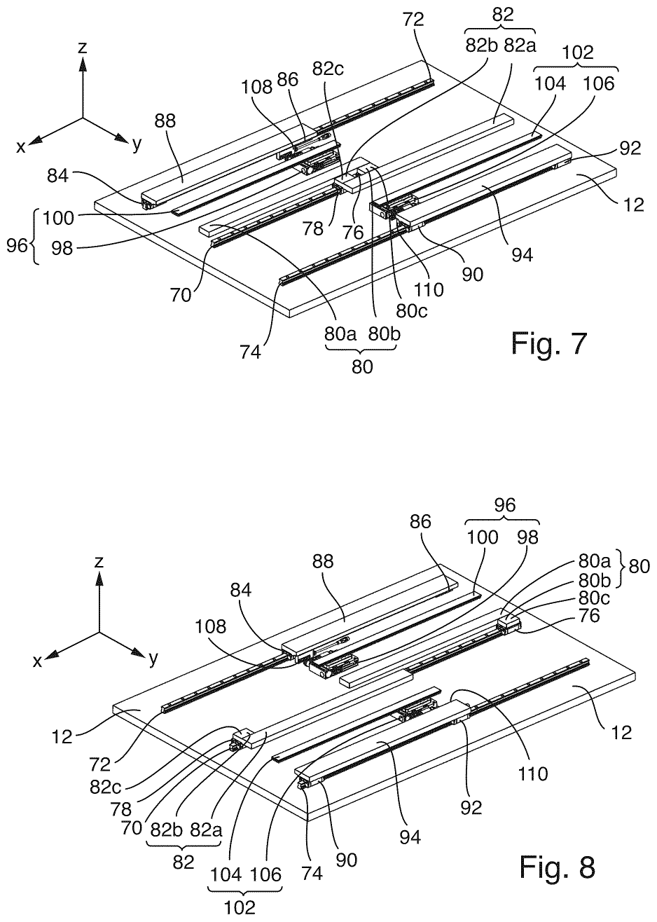

FIG. 7: shows the guides and drives of the base plates according to FIG. 3 to 6 with the left drive in the front position and the right drive in the rear position;

FIG. 8: shows the guides and drives of the base plates according to FIG. 3 to 7 without base plates with the left drive in the rear position and the right drive in the front position;

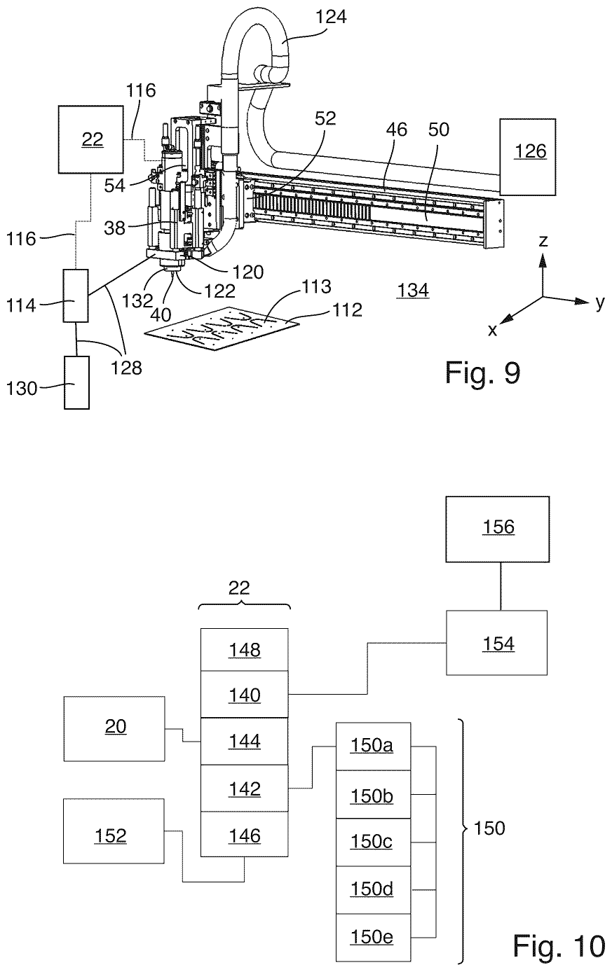

FIG. 9: shows the movable separating head from FIGS. 1 and 2 with an extraction apparatus and a printed circuit board; and

FIG. 10: is a diagram for visualizing the interconnection of a control unit of the separating machine according to FIG. 1 with other components of the separating machine.

FIG. 1 shows a separating machine 10 for separating individual printed circuit boards from a printed circuit board panel, having a machine frame 12, a cover 14, two loading compartments 16 and 18, and a user interface 20. A Cartesian coordinate system with an X, Y and Z axis is shown in order to assign the directions.

The separating machine 10 also comprises a control unit 22, which is shown in FIG. 9.

The user interface 20 comprises a light column 24 and a screen 26 as displays, as well as a keyboard 28 and a scanner 30 as an input.

The machine frame 12, on which the separating machine 10 is mounted, stands on a total of four height-adjustable machine feet 32.

Furthermore, in FIG. 1, a movable separating head 38 is visible through a transparent element 34 in the front side 36 of the cover 14, which may in particular be made of glass or plastics material. The separating head 38, which can also be seen in FIG. 2, can process a printed circuit board panel 112 (in FIG. 9) inserted into one of the loading compartments 16 or 18 using a separating tool 40 (shown in FIG. 9).

The movable separating head 38 can be moved along a y-axis by means of an axis drive 44. The axis drive 44 may be designed as a linear direct drive and is arranged on a cross-member 46 of a gantry 48 (shown in FIG. 2). The axis drive 44 has a guide 50 and a guide carriage 52. The separating head 38 is arranged on the guide carriage 52 with a further axis drive 54 for moving the separating head 38 along a z-axis extending perpendicular to the y-axis.

A base plate 56, 58 (shown in FIG. 2) on which a printed circuit board panel can each be arranged is arranged in the loading compartments 16 and 18 and can each be moved along an x-axis extending perpendicular to the y-axis and z-axis. The base plates 56 and 58 can, in particular, be moved parallel to and independently of one another. Each of the loading compartments 16 and 18 has a cover 60 and 62 that can be moved along the y-axis. In FIG. 1, the left loading compartment 16 is covered by the left cover 60, the right loading compartment 18 is open, and the right cover 62 is pushed under the left cover 60 in the y-direction. Both covers 60 and 62 are closable and are closed by the control unit 22 when a printed circuit board panel is being processed on the relevant base plate 56 or 58 or when the base plate 56 or 58 is not in the loading compartment 16 or 18. The loading compartments 16 and 18 are spatially separated from one another by a partition wall 64.

In FIG. 2, the separating machine 10 according to FIG. 1 is shown without the cover 14, the user interface 20, and the loading compartments 16 and 18. This makes the interior of the separating machine 10, in particular the gantry 48 and the movable base plates 56 and 58, visible. The x-axis, y-axis, and z-axis are shown as arrow directions. Furthermore, perpendicular columns 66 of the gantry 48 on which the cross-member 46 is arranged are shown. It can be seen that the separating head 38 is only movable along the y-axis and along the z-axis; the separating head 38 is not movable along the x-axis and is thus rigidly arranged on the cross-member 46.

As is clear from FIG. 3 to 8, there are three guide rails 70, 72 and 74 which are arranged on the machine frame 12. The base plates 56 and 58 are guided along the x-axis by means of the guide rails 70, 72 and 74 using guide carriages 76, 78, 84, 86, 90 and 92 (FIG. 3 to 8).

The central guide rail 70 has a dual function because it guides both base plates 56 and 58, for which purpose a guide carriage 76 or 78 (FIG. 3 to 8) is provided for each base plate 56 and 58. Carrier parts 80 and 82 (FIG. 3 to 8) that are each L-shaped in plan view are arranged between the base plates 56 and 58 and the relevant guide carriages 76 and 78. The left base plate 56 and the carrier part 80 are arranged on the guide carriage 76 and the right base plate 58 with the carrier part 82 are arranged on the guide carriage 78. The L-shaped carrier parts 80 and 82 have an elongate portion 80a and 82a which extends over the entire length of the relevant base plate 56 or 58 and a short rectangular portion 80b or 82b which extends parallel to the elongate portion 80a or 82a and is arranged at one end of the elongate portion 80a or 82a. The two short rectangular portions 80b or 82b are each arranged on the respective opposing long sides of the elongate portions 80a or 82a. On this short rectangular portion 80b or 82b, the relevant guide carriage 76 or 78 of the base plate 56 or 58 is arranged on the first, central guide rail 70. In addition, sliding surfaces or rolling elements may be provided on the upper side 80c and 82c of the short rectangular portions 80b and 82b.

The outer guide rails 72 and 74 each guide only one of the base plates 56 or 58. The guide rail 72 is located to the left of the central guide rail 70 and the guide rail 74 is located to the right of the central guide rail 70. Two guide carriages 84 and 86 are arranged on the left guide rail 72, on which guide carriages a strip-like carrier part 88 is arranged which connects the guide carriages 84 and 86 (FIGS. 7 and 8). The base plate 56 is arranged on the carrier part 88 and is guided by the guide rail 72. Two guide carriages 90 and 92 are also arranged on the right guide rail 74, on which guide carriages a strip-like carrier part 94 is arranged which connects the guide carriages 90 and 92 to one another (FIGS. 7 and 8). The base plate 58 is arranged on the carrier part 94 and is thus guided by the guide rail 74.

In FIG. 3, the base plates 56 and 58 are in the same front loading position. In FIG. 4, the base plate 58 is in the front loading position and the base plate 56 is in a rear separating position. In the separating position, a printed circuit board panel arranged on the base plate 56 or 58 can be processed by the separating tool 40 of the separating head 38.

In FIG. 5, the base plate 56 is not shown in order to allow for a view of a linear direct drive 96 located under the base plate 56. The linear direct drive 96 comprises a motor part 98 and a magnetic rail 100. The magnetic rail 100 is arranged on the lower side of the base plate 56. A linear direct drive 102 designed so as to correspond to the linear direct drive 96 and having a magnetic rail 104 and a motor part 106, which is shown in FIG. 6 to 8, is arranged below the base plate 58. This type of arrangement, i.e., of a moving magnetic rail 100 and 104 and a stationary motor part 98 and 106, is advantageous because the motor parts 98 and 106 are fixedly arranged on the machine frame 12, eliminating the need for a cable carrier that is otherwise usually used to route and protect cables (not shown), which are required to supply the motor parts 98 in 106 with electrical energy and to transmit control signals from the control unit 22. In this type of arrangement, the cabling is only done on the stationary components and not on the moving components.

FIG. 5 shows a reading head 108 of a position measuring system for measuring the position of the base plate 56 in the x-direction. A signal generator 109 (FIG. 6) for the reading head 108 is mounted on the lower side of the carrier part 88. A signal generator 109 of this kind may, for example, be a magnetic tape which extends over the entire length of the relevant base plate 56 or carrier part 88 in the x-direction and which forms an incremental measuring system with the reading head 56. An identical measuring system is also provided for the base plate 58 with a reading head 110 and a signal generator 111, shown in FIG. 6. The position of the base plates 56 and 58 is transmitted from the incremental measuring system to the control unit 22, since the linear drives 96 and 102 move the base plates 56 and 58 along the x-axis during the separation process; the separating head 38 cannot be moved along the x-axis, as stated above.

FIG. 6 is a front view of the base plates 56 and 58 with guide rails 70, 72 and 74 and the linear direct drives 96 and 102 according to FIG. 3. The reading head 110 is shown here arranged below the carrier part 94 on the machine frame. The front view clearly shows that the base plates 56 and 58 can rest on the surfaces 80c or 82c on the L-shaped carrier part 80 or 82 of the other base plate 56 or 58 in each case. This increases the stability of the base plates 56 and 58, in particular when a force acts in the z-direction when a printed circuit board panel is being processed. A coating or rolling element (not shown) may be provided on the surfaces 80c and 82c to reduce the friction between the relevant surface 80c or 82c and the base plate 58 or 56.

FIG. 7 is a detail view of the carrier parts 88, 80, 82 and 94 with the guide carriages 76, 78, 84, 86, 90 and 92 arranged on the guide rail 70, 72 and 74, and the linear direct drives 96 and 102. As mentioned above, the L-shape of the carrier parts 80 and 82 can be clearly seen here. The carrier parts 80 and 84 associated with the base plate 56 and having the associated guide carriages 76 and 84, 86, as well as the linear direct drive 96 are in the front loading position. The carrier parts 82 and 94 associated with the base plate 58 and having the associated guide carriages 78 and 90, 92, as well as the linear direct drive 102 are in the rear separating position.

FIG. 8 shows the detail view according to FIG. 7, but the components associated with the base plates 56 or 58 are shown in an opposite position compared to the view in FIG. 7. The components of the base plate 56 are in the rear separating position and the associated components of the base plate 58 are in the front loading position.

FIG. 9 shows the separating head 38 having the separating tool 40, in this case a milling cutter, and the axis drive 54 for the z-axis, which is arranged on the cross-member 46 of the gantry 48. The columns 66 of the gantry 48 are not shown. A printed circuit board panel 112 being processed and having a plurality of identical printed circuit boards 113 to be separated from the printed circuit board panel 112 is shown below the separating head 38. Other components of the separating machine 10, such as the machine frame 12, are not shown here or are only shown schematically.

Furthermore, the control unit 22 is shown schematically, which is connected to the separating head 38 and to an electrical switching valve 114 via data lines 116. An extraction apparatus 120 is arranged on the separating head 38. The extraction apparatus 120 forms an extraction opening 122 surrounding the separating head 38. The extraction apparatus 120 is configured such that particles generated during processing of the printed circuit board panel 112 are drawn off. For this purpose, the extraction apparatus 120 is connected to a vacuum source 126 via vacuum lines 124. To improve detachment of the resulting particles from the printed circuit board panel 112, at least one, preferably three compressed air nozzles are provided in the extraction apparatus 120, which direct a relevant compressed air flow in a relevant main air flow direction on the printed circuit board panel 112. The at least one compressed air nozzle is connected via a compressed air line 128 to a switching valve 114, which influences ionized compressed air from a compressed air source 130 in such a way that the compressed air flow flowing out of the at least one compressed air nozzle pulsates at a pulse frequency. By means of at least one pulsating compressed air flow, the detachment of particles adhering to the printed circuit board panel 112 can be improved and thus the capture and extraction can be carried out more efficiently. The detachment of particularly small particles in the range of less than 80 um is promoted when the pulse frequency of the at least one compressed air flow is transferred to the printed circuit board panel 112 and electrostatic forces which cause the small particles to adhere to the printed circuit board panel can be reduced by the ionized state of the compressed air. A brush ring 132 is arranged on the extraction apparatus 120 and surrounds the separating tool 40 and rests on the printed circuit board panel 112 during the separation processing. Said brush ring 132 seals the extraction opening 122 off from the environment 134 such that the vacuum built up by the vacuum source 126 can develop up to the printed circuit board panel 112 and thus the volume of the particles and the at least one blown-in compressed air flow can be drawn off.

FIG. 10 schematically shows the interconnection of the control unit 22 with the various modules thereof and various components of the separating machine 10. The control unit 22 comprises a process control module 140, a machine control module 142, a user interface module 144, a camera module 146, and an image processing module 148. The modules 140-148 are interconnected within the control unit 22 and can exchange data with one another. The linear direct drives 96 and 102, as well as the axis drives 44 and 54, which may be designed as linear direct drives, each comprise a drive controller 150a to 150d, which are shown as an interconnected arrangement 150. The machine control module 142 of the control unit 22 is configured such that it can communicate with the relevant drive controller 150a to 150d of the controller arrangement 150.

A camera system 152, shown schematically in FIG. 10, can be provided on the separating machine 10. The camera system 152 comprises at least one camera. The camera system 152 can be used, for example, to record the printed circuit board panel 112 during the separation process. For this purpose, the camera module 146 of the control unit 22 is configured such that it can communicate with the camera system 152 and can transmit the data of the camera system 152 to the image processing module 148 for processing and evaluating the recorded image data. Depending on this, the control unit 22 can generate signals for controlling the drive controllers 150a to 150d.

The user interface module 144 of the control unit 22 is configured to communicate with the user interface 20 and to display process data on the screen 26 or light column 24 or to receive control commands from the keyboard 28 or scanner 30.

The process control module 140 is configured to communicate with a process control system 154. Via the process control system, the separating machine 10 can access a database 156 by means of the control unit 22 in order to, for example, retrieve workpiece parameters for more efficient processing of the printed circuit board panel 112.

1-28. (canceled)

29. A separating machine for separating individual printed circuit boards from a printed circuit board panel,
having a separating head that has a separating tool and that can be moved on a machine frame, the separating head being movable by axis drives along a vertical z-axis and a y-axis extending perpendicular thereto,
having at least two base plates which can be moved on the machine frame parallel to one another along an x-axis extending perpendicular to the z-axis and perpendicular to the y-axis between a loading position and a separating position by linear direct drives,
wherein at least one printed circuit board panel can be arranged on each of the base plates, wherein the linear direct drives each comprise a motor part and each comprise a magnetic rail that interacts with the motor part, and
having a control unit for actuating the axis drives, the separating head, and the linear direct drives, wherein the control unit is configured such that the separating tool separates individual printed circuit boards from a printed circuit board panel during separation processing, and in that the linear direct drives can be controlled independently of one another, such that one base plate is in the loading position and the other base plate is in the separating position for the separation processing,
wherein the control unit is configured in such a way that during the separation processing in the separating position when a printed circuit board panel is arranged on the base plate and is processed by the separating tool of the separating head, a relative movement between the base plate and the separating head in the direction of the x-axis takes place by actuating the relevant linear direct drive.

30. The separating machine according to claim 29, wherein the separating tool is designed as a milling cutter and/or saw and/or knife.

31. The separating machine according to claim 29, wherein the relevant motor part of the linear direct drives is arranged in a fixed position on the machine frame and the relevant magnetic rail is arranged on the relevant base plate.

32. The separating machine according to claim 29, wherein the relevant motor part is designed to be guide-free and wherein guide rails are provided at a distance from the relevant motor part to guide the base plates on the machine frame.

33. The separating machine according to claim 32, wherein three guide rails having guide carriages and extending parallel to one another are provided for guiding two base plates, wherein a first guide carriage for the first base plate and a second guide carriage for the second base plate are provided on a first, central guide rail.

34. The separating machine according to claim 33, wherein the second and third guide rails each have at least one and preferably two guide carriages, wherein the guide carriage(s) of the second guide rail is/are provided for guiding the first base plate and the guide carriage(s) of the third guide rail is/are provided for guiding the second base plate.

35. The separating machine according to claim 33, wherein carrier parts are provided between the relevant base plate and the relevant guide carriages.

36. The separating machine according to claim 35, wherein, when two guide carriages are provided on a guide rail for a base plate, a common carrier part is provided between the two guide carriages and the base plate.

37. The separating machine according to claim 35, wherein a carrier part which is L-shaped in plan view is provided in each case on the first, central guide rail between the first guide carriage and the first base plate and/or between the second guide carriage and the second base plate.

38. The separating machine according to claim 35, wherein a base plate is supported and/or guided in the region of the first, central guide rail by the carrier part of the other base plate.

39. The separating machine according to claim 29, wherein a position measuring system is provided for detecting the position of the relevant base plates, wherein the position measuring system in each case has a sensor arranged in a fixed position on the machine frame and a signal generator on the relevant base plate which interacts with the sensor.

40. The separating machine according to claim 29, wherein at least two loading compartments are provided, in each of which a base plate in the loading position thereof can be loaded with a printed circuit board panel independently of the other loading compartment.

41. The separating machine according to claim 29, wherein the separating head is arranged on a gantry in a rigid/non-movable manner in the x-axis direction.

42. The separating machine according to claim 29, wherein the axis drives of the separating head are designed as linear direct drives, each consisting of a carriage and a guide and in which the drive force is transmitted directly without mechanical transmission elements.

43. The separating machine according to claim 29, wherein the linear direct drives and axis drives each have a drive controller, and wherein the control unit is designed to communicate with the relevant drive controller.

44. The separating machine according to claim 29, wherein the control unit comprises a process control module for communication with a process control system and/or a machine control module for communication with the drive controllers.

45. The separating machine according to claim wherein the control unit is configured to access a database via the process control system.

46. The separating machine according to claim 29, wherein a camera system having at least one camera and a data interface is provided and is configured to record the circuit board panels.

47. The separating machine according to claim 46, wherein the control unit comprises an image processing module and a camera module for communication with the camera system.

48. The separating machine according to claim 29, wherein the control unit comprises a user interface module for communication with a user interface, and wherein process data are displayed on the user interface and/or control commands are entered via the user interface and transmitted to the control unit.
